(19) United States
(12) Patent Application Publication
(10) Pub. No.: US 2025/0323020 A1
(43) Pub. Date: Oct. 16, 2025

(54) PLASMA ETCHING DEVICE AND METHOD OF OPERATING THE SAME

(71) Applicant: Samsung Electronics Co., Ltd., Suwon-si (KR)

(72) Inventors: MinSeok SEO, Suwon-si (KR); SEUNGHUN KIM, Suwon-si (KR); Donghoon PARK, Suwon-si (KR)

(21) Appl. No.: 18/929,001

(22) Filed: Oct. 28, 2024

(30) Foreign Application Priority Data
Apr. 15, 2024 (KR) 10-2024-0049962
May 3, 2024 (KR) 10-2024-0059059

(51) Int. Cl. H01J 37/32

(52) U.S. Cl. CPC H01J 37/32174; H01J 37/3211; H01J 37/32128; H01J 2237/3341

(57) ABSTRACT

A plasma etching device includes a source power generator configured to generate a source power signal based on a source control signal, a bias power generator configured to generate a bias power signal based on a bias control signal, an inductively-coupled antenna provided with the source power signal, a wafer support member connected to the bias power generator and receiving the bias power signal from the bias power generator, a chamber including the wafer support member and containing plasma generated by source power signal, and a memory configured to store frequency information. The source power generator detects whether the bias power generator is operating, and performs, in response to detecting of the bias power generator being operating, a frequency switching operation. In the frequency switching operation, a frequency of the source power signal is set to a frequency value of the frequency information.

### CROSS-REFERENCE TO RELATED APPLICATIONS

This application claims priority under 35 U.S.C. § 119 to Korean Patent Application No. 10-2024-0049962 filed on Apr. 15, 2024, and No. 10-2024-0059059 filed on May 3, 2024, in the Korean Intellectual Property Office, the disclosures of which are incorporated by reference herein in their entireties.

### BACKGROUND

Embodiments of the present disclosure described herein relate to a plasma etching device, and more particularly, relate to a device for generating plasma by using a source power signal and a bias power signal, and a method of operating the plasma etching device.

An inductively-coupled-plasma (ICP) etching device is used to form micro-patterns or structures of semiconductor elements in a process of manufacturing semiconductors and electronic devices. In general, the ICP etching device is used to form the micro-patterns or structures of semiconductor elements.

The ICP etching device performs an etching process by generating electrically-activated plasma. ICP etching is commonly used with several active gases. These gases generate plasma and induce chemical reactions on a semiconductor surface, thereby accurately controlling micro-patterns. To implement high-resolution and high-accuracy etching, it is necessary to adjust the frequency of power applied to a coil in the ICP etching.

### SUMMARY

Embodiments of the present disclosure provide a plasma etching device for reducing reflection loss due to frequency changes.

According to an embodiment, a plasma etching device includes a source power generator that generates a source power signal based on a source control signal, a bias power generator that generates a bias power signal based on a bias control signal, an inductively-coupled antenna provided with the source power signal, and a plasma generating device provided with the bias power signal. The source power generator is configured to detect whether the bias power generator is operating, and performs, in response to detecting of the bias power generator being operating, a frequency switching operation by switching a frequency of the source power signal.

According to an embodiment of the present disclosure, a device includes a control circuit configured to generate a frequency control signal to control a frequency of a source power signal, an RF generator configured to generate the source power signal based on the frequency control signal, a monitoring circuit configured to determine whether a bias power generator is operating, and a memory configured to store frequency information. The control circuit performs a frequency switching operation based on the frequency information in response to the monitoring circuit determining that the bias power generator is operating.

According to an embodiment, a method of operating a device including a source power generator and a bias power generator includes determining, by the monitoring circuit, whether the bias power generator is operating, and performing, by the control circuit, a frequency switching operation based on the frequency information in response to a result of determining that the bias power generator is operating. The source power generator includes a control circuit that generates a frequency control signal including information for controlling a frequency of a source power signal, an RF generator that generates the source power signal based on the frequency control signal, and a monitoring circuit that detects whether a bias power generator is operating, and a memory that stores frequency information.

### BRIEF DESCRIPTION OF THE FIGURES

The above and other objects and features of the present disclosure will become apparent by describing in detail embodiments thereof with reference to the accompanying drawings.

FIG. 1 is a diagram showing an example of a plasma etching device, according to an embodiment of the present disclosure.

FIG. 2 is a diagram showing an example of a source power generator, according to an embodiment of the present disclosure.

FIG. 3 is a diagram showing an example of a source power generator, according to an embodiment of the present disclosure.

FIG. 4 is a diagram showing an example of a source power generator, according to an embodiment of the present disclosure.

FIG. 5 is a flowchart showing an example of a method for manufacturing a semiconductor device, according to an embodiment of the present disclosure.

FIG. 6 is a flowchart showing an example of an etching process method, according to an embodiment of the present disclosure.

FIG. 7 is a flowchart showing an example of a frequency switching operation, according to an embodiment of the present disclosure.

FIG. 8 is a graph showing a frequency switching operation performed in an initial cycle of a semiconductor manufacturing process.

FIG. 9 is a graph showing a frequency switching operation performed in an N-th cycle of a semiconductor manufacturing process.

### DETAILED DESCRIPTION

Hereinafter, embodiments of the present disclosure may be described in detail and clearly to such an extent that an ordinary one in the art easily implements the present disclosure.

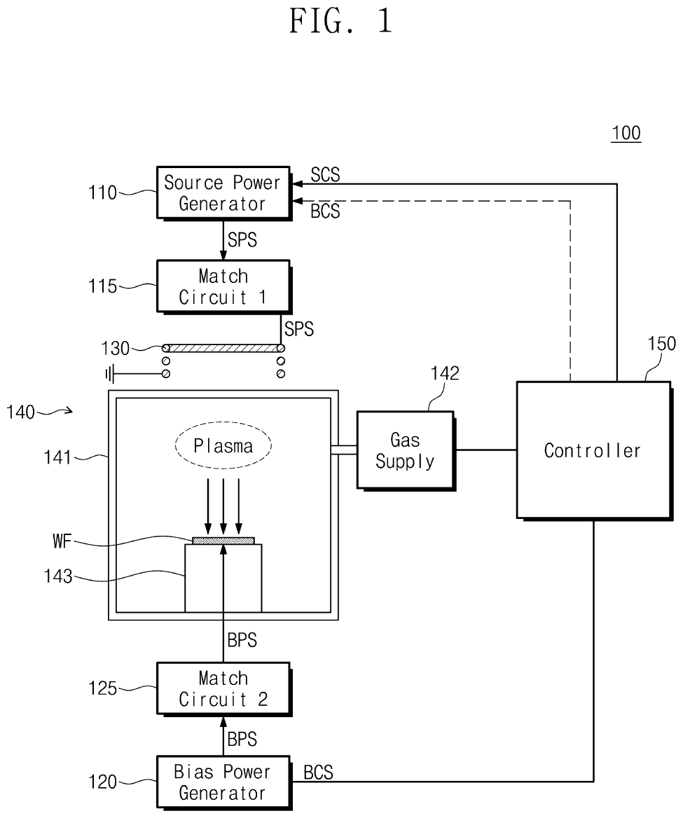

FIG. 1 is a diagram showing an example of a plasma etching device, according to an embodiment of the present disclosure. In an embodiment, a plasma etching device 100 (i.e., plasma etching equipment) may be an ICP etching device used to etch a wafer WF.

A configuration of the ICP etching device may be appropriately modified and/or utilized according to examples provided in the specification. In an embodiment, the ICP etching device disclosed in FIG. 1 may be modified to be part of another ICP etching device. For example, the ICP etching device may be modified from one of the ICP etching devices disclosed in U.S. patent application Ser. No. 12/182,342, entitled “FIELD ENHANCED INDUCTIVELY COUPLED PLASMA (FE-ICP) REACTOR,” filed Jul. 30, 2008 by Valentin N. Todorow et al., U.S. Provisional Patent Application No. 61/254,833, entitled “INDUCTIVELY COUPLED PLASMA APPARATUS,” filed Oct. 26, 2010 by Valentin N. Todorow et al., and U.S. Provisional Patent Application No. 61/254,837, entitled “DUAL MODE INDUCTIVELY COUPLED PLASMA WITH ADJUSTABLE PHASE COIL ASSEMBLY,” filed on Oct. 26, 2010 by Samer Banna et al.

For example, the plasma etching device 100 according to an embodiment of the present disclosure is applicable to all types of ICP devices that use source power RF power and/or bias power RF power. These plasma etching devices may include a plasma annealing device, a plasma-enhanced chemical vapor deposition device, a physical vapor deposition device, and a plasma cleaning device.

Referring to FIG. 1, in an embodiment, the plasma etching device 100 may include a source power generator 110, a first match circuit 115, an inductively-coupled antenna 130, a plasma generating device 140, a bias power generator 120, a second match circuit 125, and a controller 150.

The source power generator 110 may be configured to generate a source power signal SPS based on a source control signal SCS received from the controller 150. The source control signal SCS may include information for controlling an operation of the source power generator 110. For example, the source power generator 110 may be turned on based on the activation of the source control signal SCS and may be turned off based on the deactivation of the source control signal SCS.

The first match circuit 115 may be connected between the source power generator 110 and the inductively-coupled antenna 130. For example, an input terminal of the first match circuit 115 may be connected to the output terminal of the source power generator 110. An output terminal of the first match circuit 115 may be connected to the inductively-coupled antenna 130. The first match circuit 115 may be configured to match impedance at the input terminal and impedance at the output terminal.

The first match circuit 115 may include a capacitor and an inductor. The capacitor may be a fixed capacitance capacitor or a variable capacitance capacitor. The inductor may be a fixed inductance inductor or a variable inductance inductor. In an embodiment, the first match circuit 115 may be an L-type match circuit. The present disclosure is not limited thereto. In an embodiment, the first match circuit 115 may be a pie-type match circuit.

The source power signal SPS generated by the source power generator 110 may be provided to the inductively-coupled antenna 130 through the first match circuit 115.

The inductively-coupled antenna 130 may be configured to generate inductively-coupled energy based on the source power signal SPS. For example, the inductively-coupled antenna 130 may include a coil. One end of the coil may be connected to the output terminal of the first match circuit 115, and the other end of the coil may be grounded.

The source power signal SPS may be applied to the coil to supply induced electromotive force to the plasma generating device 140. As the induced electromotive force is supplied to gas molecules inside a chamber 141 of the plasma generating device 140, plasma may be generated inside the chamber 141. For example, electrons may be accelerated by a magnetic field generated inside the chamber 141 and may collide with the gas molecules to generate radicals and ions.

The plasma generating device 140 may include the chamber 141, a gas supply 142, and a wafer support member 143. The chamber 141 may be a cylindrical chamber, but is not limited thereto. The chamber 141 may be placed under the inductively-coupled antenna 130. To generate plasma inside the chamber 141, the gas supply 142 may supply gas. The gas may include argon gas, oxygen gas, nitrogen gas, chloride gas, or a mixture of at least two or more of these gases. The wafer support member 143 may be placed on a bottom surface inside the chamber 141. The wafer support member 143 may be a cathode electrode and may be configured to deliver a bias power signal BPS to the wafer. The radicals of plasma inside the chamber 141 may be accelerated onto the wafer by the electric field formed as the bias power signal BPS may be applied to the wafer support member 143. For example, the radicals with a net electric charge may be accelerated toward the wafer by the electric field. Accordingly, etching may be made when the accelerated radicals collide with parts exposed by a pattern of a photo mask on the top surface of the wafer. In an embodiments, ions in plasma may be accelerated toward the wafer by the electric field.

The bias power generator 120 may be configured to generate the bias power signal BPS based on a bias control signal BCS received from the controller 150. The bias control signal BCS may include information for controlling an operation of the bias power generator 120. For example, the bias power generator 120 may be turned on based on a turn-on signal of the bias control signal BCS. The bias power generator 120 may be turned off based on a turn-off signal of the bias control signal BCS.

The second match circuit 125 may be connected between the bias power generator 120 and the plasma generating device 140. For example, an input terminal of the second match circuit 125 may be connected to the output terminal of the bias power generator 120. An output terminal of the second match circuit 125 may be connected to the wafer support member 143. The second match circuit 125 may be configured to match impedance at the input terminal and impedance at the output terminal.

The second match circuit 125 may include a capacitor and an inductor. The capacitor may be a fixed capacitance capacitor or a variable capacitance capacitor. The inductor may be a fixed inductance inductor or a variable inductance inductor. In an embodiment, the second match circuit 125 may be an L-type match circuit. The present disclosure is not limited thereto. In an embodiment, the second match circuit 125 may be a pie-type match circuit.

The bias power signal BPS generated by the bias power generator 120 may be delivered to the wafer WF through the wafer support member 143. The bias power signal BPS may be an RF power signal applied to the support member of the wafer.

The controller 150 may be configured to perform an etching process by controlling the source power generator 110, the plasma generating device 140, and the bias power generator 120. The controller 150 may be connected to the source power generator 110, the plasma generating device 140, and the bias power generator 120 through various interfaces including analog, digital, wired, wireless, optical, or fiber-optic interfaces.

The controller 150 may include a processor. The processor may be one of arbitrary types of general-purpose computer processors capable of being used in industrial environments to control the plasma generating device 140. For example, the processor may be a central processing unit (CPU).

The controller 150 may include a computer-readable storage medium configured to store various commands for performing an etching process. For example, the storage medium may include a memory 113, such as a random access memory, a read only memory, a floppy disk, a hard disk, and any other form of local or remote digital storage device.

For example, process instructions, such as etch or other process instructions, are stored on a storage medium as software routines known as recipes. The software routine may be stored and/or executed remotely from the processor or another processor, which is provided external to the controller 150.

When the software routines are executed by the processor, a general-purpose computer may be converted into a special-purpose computer having the specific purpose of generating and controlling plasma during the etch process. As such, the controller 150 may be implemented as software running on a computer system, hardware as an application-specific integrated circuit or other type of hardware implementation, or a combination of software and hardware.

The controller 150 may further include support circuits of a cache, a power supply device, a clock circuit, an input/output circuit, or related subsystems.

The source power generator 110 may be configured to optimize the frequency of the source power signal SPS. In an embodiment, the source power generator 110 may perform a frequency tuning operation such that the magnitude of the output current increases. For example, when the output current of the source power generator 110 increases in the case where the frequency of the source power signal SPS increases by a specific interval, the source power generator 110 increases the frequency of the source power signal SPS again by the specific interval again. When the output current of the source power generator 110 decreases in the case where the frequency of the source power signal SPS increases by the specific interval, the source power generator 110 decreases the frequency of the source power signal SPS by the specific interval. For example, when the output current of the source power generator 110 increases in the case where the frequency of the source power signal SPS decreases by the specific interval, the source power generator 110 decreases the frequency of the source power signal SPS again by the specific interval again. When the output current of the source power generator 110 decreases in the case where the frequency of the source power signal SPS decreases by the specific interval, the source power generator 110 increases the frequency of the source power signal SPS by the specific interval. According to this method, the frequency of the source power signal SPS may converge to a value at which the magnitude of the current output from the source power generator 110 is maximized. For example, to obtain a high-density plasma, the output current of the source power generator 110 may be increased or may have a maximum current at a given process condition including a pressure of a gas in the chamber by the frequency tuning operation.

The case where the magnitude of the current output from the source power generator 110 is maximized may correspond to a case where the impedance at the input terminal of the first match circuit 115 matches the impedance at the output terminal of the first match circuit 115. In other words, the source power generator 110 may be configured to optimize a frequency based on the impedance at the input terminal of the first match circuit 115 and the impedance at the output terminal of the first match circuit 115.

The impedance at the output terminal of the first match circuit 115 may vary based on the plasma generating device 140 connected to the output terminal and the bias power generator 120. For example, when the bias power generator 120 does not operate, the impedance of the output terminal of the first match circuit 115 may have a first impedance value, and the source power generator 110 may converge the frequency of the source power signal SPS to a first frequency corresponding to the first impedance value. Afterwards, when the bias power generator 120 operates, the impedance of the output terminal of the first match circuit 115 may have a second impedance value different from the first impedance value, and the source power generator 110 may converge the frequency of the source power signal SPS to a second frequency corresponding to the second impedance value.

When the impedance value at the output terminal of the source power generator 110 changes suddenly (e.g., when the bias power generator does not operate and then starts operating), a portion of the source power signal SPS provided from the source power signal SPS to the first match circuit 115 is reflected, thereby resulting in reflection loss of the source power signal SPS. The amount of reflection loss may increase depending on the time required for the frequency of the source power signal SPS to change from the first frequency to the second frequency. Accordingly, the amount of the source power signal SPS delivered to the plasma generating device 140 connected to the output terminal of the first match circuit 115 is reduced, and thus quality defects may occur when the etching process is performed. To suppress the quality defects, when the source power generator 110 consumes more power to offset the reflection loss, equipment failure may occur.

In an embodiment of the present disclosure, the source power generator 110 may be configured to detect an operation of a bias power circuit based on a signal from an output terminal. In another embodiment, the source power generator 110 may be configured to detect an operation of a bias power circuit based on the bias control signal BCS generated from the controller 150. The source power generator 110 may be configured to perform a frequency switching operation based on the detection result. In the case of the present disclosure, the amount of reflection loss of the source power signal SPS may be reduced by performing the frequency switching operation.

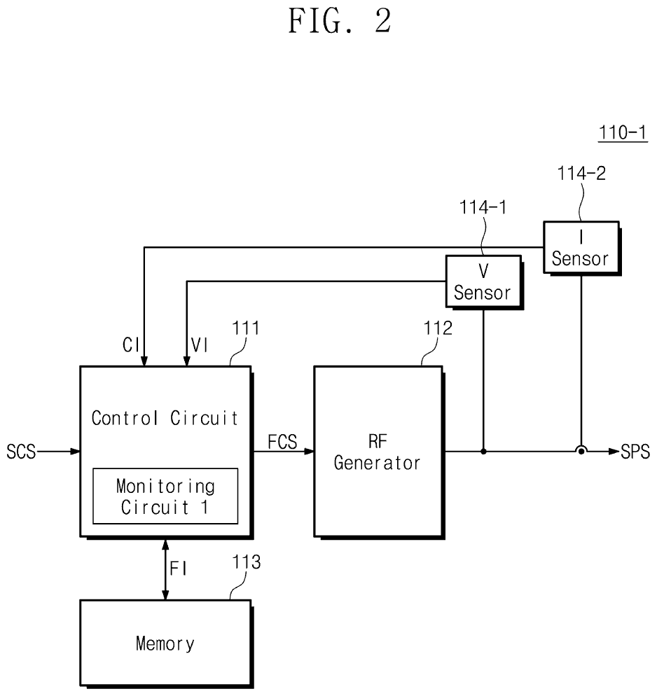

Hereinafter, the specific configuration and operation of the source power generator 110 will be described through FIGS. 2 to 4.

FIG. 2 is a diagram showing an example of a source power generator, according to an embodiment of the present disclosure. Hereinafter, an embodiment of the source power generator 110-1 of FIG. 1 will be described in detail with reference to FIG. 2.

In an embodiment, a source power generator 110-1 may include a control circuit 111, an RF generator 112, a memory 113, a voltage sensor 114-1, and a current sensor 114-2. The control circuit 111 may be configured to generate a frequency control signal FCS based on the source control signal SCS. The frequency control signal FCS may include information for controlling the frequency of the source power signal SPS generated by the RF generator 112.

The RF generator 112 may be configured to generate the source power signal SPS based on the frequency control signal FCS. The frequency of the source power signal SPS may be set based on the frequency control signal FCS.

The voltage sensor 114-1 may be configured to measure the voltage of the output terminal of the RF generator 112. For example, the voltage sensor 114-1 may be an alternating current (AC) voltage sensor 114-1 configured to measure an AC voltage applied to an output terminal. The voltage sensor 114-1 may be configured to provide the control circuit 111 with voltage information VI including information about the measured voltage (e.g., a measured AC voltage value).

The current sensor 114-2 may be configured to measure a current flowing from the output terminal of the RF generator 112 to the first match circuit 115. For example, the current sensor 114-2 may be an analog sensor configured to measure an alternating current output from the output terminal. The current sensor 114-2 may be configured to provide the control circuit 111 with current information CI including information about the measured current (e.g., a measured AC current value).

The control circuit 111 may include a first monitoring circuit configured to detect an operation of the bias power generator 120. However, embodiments are not limited thereto. For example, the first monitoring circuit may be provided separately from the control circuit 111. The first monitoring circuit may be configured to determine whether the bias power generator 120 is operating, based on the voltage information VI and the current information CI. In an embodiment, the first monitoring circuit may determine whether the bias power generator 120 is operating, based on at least one of the voltage information VI and the current information CI.

In an embodiment, the first monitoring circuit may detect the operation of the bias power generator 120 based on the magnitude of the voltage information VI. For example, the first monitoring circuit may calculate the effective value of the AC voltage (i.e., the effective voltage) from the voltage information VI and may output the calculated result as the magnitude of the voltage information VI. The effective value of the AC voltage is a root mean square (RMS) value of the AC voltage. In an embodiment, the RMS value of the AC voltage may be obtained by 1) squaring the instantaneous voltages along a sine wave of the source power signal SPS output by the source power generator 110-1; 2) calculating the average of the squared instantaneous voltages; and 3) taking the square root of the average. The first monitoring circuit may determine that the bias power generator 120 is operating, based on the result of determining that the calculated magnitude of the voltage information VI is greater than or equal to a first threshold value.

In an embodiment, the first monitoring circuit may detect the operation of the bias power generator 120 based on the magnitude of the current information CI. For example, the first monitoring circuit may calculate the effective value of alternating current (i.e., the effective current) from the current information CI and may output the calculated result as the magnitude of the current information CI. The effective value of alternating current means the RMS value of the alternating current. In an embodiment, the RMS value of the AC current may be obtained by 1) squaring the instantaneous currents along a sine wave of the source power signal SPS outputted by the source power generator 110-1; 2) calculating the average of the squared instantaneous currents; and 3) taking the square root of the average. The first monitoring circuit may determine that the bias power generator 120 is operating, based on the result of determining that the calculated magnitude of the current information CI is greater than or equal to a second threshold value.

In an embodiment, the first monitoring circuit may detect the operation of the bias power generator 120 based on the magnitude of the voltage information VI and the magnitude of the current information CI. For example, the first monitoring circuit may determine that the bias power generator 120 is operating, based on the result of determining that the magnitude of the voltage information VI is greater than or equal to the first threshold value, and the magnitude of the current information CI is greater than or equal to the second threshold value.

When the first monitoring circuit determines that the bias power generator 120 is operating, the control circuit 111 may be configured to perform a frequency switching operation based on frequency information FI stored in the memory 113. The control circuit 111 may control the RF generator 112 such that the frequency of the source power signal SPS is maintained at a constant value for a specific period of time. For example, the frequency of the source power signal SPS may be maintained constantly for a period of 0.1 to 10 seconds. After a frequency switching operation is performed and then a specific time has elapsed, the control circuit 111 may be configured to perform a frequency tuning operation. The frequency of the source power signal SPS may be optimized by the frequency tuning operation of the control circuit 111 such that the output current of the source power generator 110 is maximized.

The first monitoring circuit may be further configured to detect the termination of an operation of the bias power generator 120. In an embodiment, the first monitoring circuit may determine whether the operation of the bias power generator 120 has ended, based on the magnitude of the voltage information VI and the magnitude of the current information CI. For example, the first monitoring circuit may determine that the operation of the bias power generator 120 has ended, based on the result of determining that the magnitude of the voltage information VI is less than the first threshold value, or the magnitude of the current information CI is less than the second threshold value.

When the first monitoring circuit determines that the operation of the bias power generator 120 has ended, the control circuit 111 may update the frequency information FI stored in the memory 113 based on a value of the optimized frequency of the source power signal SPS immediately before the end. The updated frequency information FI may further include a value of the optimized frequency in addition to an initial frequency value.

In an embodiment, the control circuit 111 may output a mean value of frequency values during a specific period immediately before the end of operating the bias power generator 120 as the value of the optimized frequency. The present disclosure is not limited thereto. In an embodiment, the control circuit 111 may perform the frequency tuning operation and may output a convergence value of the frequency of the source power signal SPS as the value of the optimized frequency. For example, a frequency value of the source power signal SPS obtained after completing the frequency tuning operation may correspond to the convergence value.

The memory 113 may be configured to store various commands or information necessary for an operation of the control circuit 111. For example, the memory 113 may include the frequency information FI, which is the basis for the switching operation of the control circuit 111, and information about a specific time related to performing the frequency switching operation and the frequency tuning operation.

The memory 113 may include a volatile memory (e.g., dynamic random access memory (DRAM)), a non-volatile memory (e.g., a read-only memory, a floppy disk, or a hard disk), or any other form of local or remote digital storage device.

When the bias power generator does not operate and then starts operating, the impedance value at the output terminal of the source power generator 110 may change suddenly. In an embodiment of the present disclosure, the first monitoring circuit detects whether the bias power generator is operating, and performs a frequency switching operation. Accordingly, the time required to optimize the frequency of the source power signal SPS is reduced, and the amount of reflection loss may be reduced.

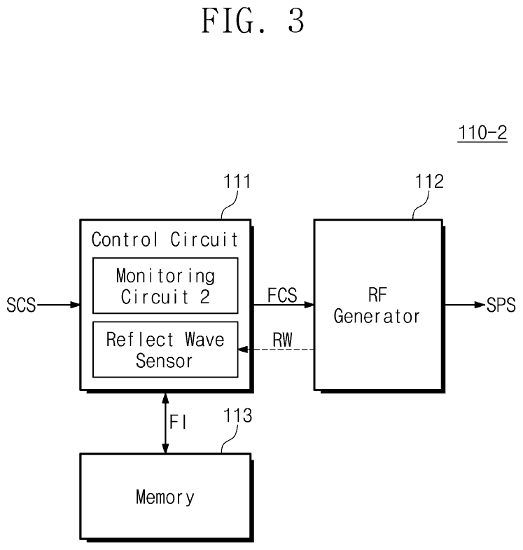

FIG. 3 is a diagram showing an example of a source power generator, according to an embodiment of the present disclosure. Hereinafter, an embodiment of a source power generator 110-2 of FIG. 1 will be described in detail with reference to FIG. 3.

In an embodiment, the source power generator 110-2 may include the control circuit 111, the RF generator 112, and the memory 113. The configurations of the RF generator 112 and the memory 113 may be substantially the same as those in FIG. 2. Hereinafter, the same operation as described in FIG. 2 will be omitted to avoid redundancy and the differences will be described.

The control circuit 111 may include a second monitoring circuit configured to detect an operation of the bias power generator 120. The control circuit 111 may further include a reflect wave sensor configured to detect a reflect wave received from the RF generator 112. However, embodiments are not limited thereto. For example, the second monitoring circuit or the reflect wave sensor may be provided as a separate device outside the control circuit 111. For example, the reflect wave sensor may be a device that measures the reflect wave of an RF signal generated by the RF generator 112, such as a spectrum analyzer, a network analyzer, an oscilloscope, and a time domain reflectometer (TDR).

In an embodiment, the second monitoring circuit may detect the operation of the bias power generator 120 based on the magnitude of the reflect wave detected by the reflect wave sensor. For example, the second monitoring circuit may output the absolute value of a mean reflection coefficient, which is a mean value of reflection coefficients, as the magnitude of the reflect wave. In an embodiment, the reflection coefficient may be a measure of how much of the radio frequency (RF) power (i.e., the source power signal) that is sent into the chamber 141 is reflected back toward the RF generator 112. This coefficient may indicate the efficiency of power transfer from the RF generator 112 to the plasma in the chamber 141. In an embodiment, the reflection coefficient may be measured multiple times in a given time period, and then may be obtained by calculating a mean value of the multiple measures of the reflection coefficient. The second monitoring circuit may determine that the bias power generator 120 is operating, based on the result of determining that the magnitude of the reflect wave is greater than or equal to a third threshold value.

When the second monitoring circuit determines that the bias power generator 120 is operating, the control circuit 111 may be configured to perform a subsequent operation of the frequency switching operation based on the frequency information FI stored in the memory 113. The subsequent operation in the control circuit 111 may be the same as those described in FIG. 2.

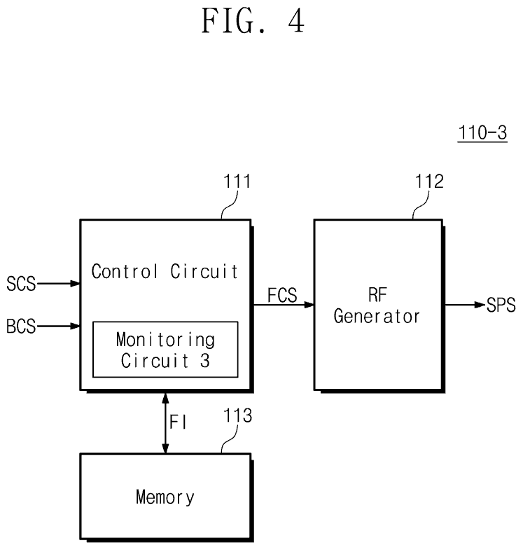

FIG. 4 is a diagram showing an example of a source power generator, according to an embodiment of the present disclosure. Hereinafter, an embodiment of a source power generator 110-3 of FIG. 1 will be described in detail with reference to FIG. 4.

In an embodiment, the source power generator 110-3 may include the control circuit 111, the RF generator 112, and the memory 113. The configurations of the RF generator 112 and the memory 113 may be substantially the same as those in FIG. 2. Hereinafter, the same operation as described in FIG. 2 will be omitted to avoid redundancy and the differences will be described.

The control circuit 111 may be further configured to receive the bias control signal BCS. The bias control signal BCS may be a signal such as a signal for controlling the operation of the bias power generator 120 (see FIG. 1).

The control circuit 111 may include a third monitoring circuit configured to detect an operation of the bias power generator 120. The third monitoring circuit may be configured to monitor the bias control signal BCS.

In an embodiment, the third monitoring circuit may detect the operation of the bias power generator 120 based on the bias control signal BCS. The bias control signal BCS may include an operating signal, which allows the bias power generator 120 to operate, and an end signal, which allows the bias power generator 120 to end. The third monitoring circuit may determine whether the bias control signal BCS is the operating signal or the end signal, and may determine that the bias power generator 120 is operating, based on the result of determining that the bias control signal BCS is the operating signal.

When the third monitoring circuit determines that the bias power generator 120 is operating, the control circuit 111 may be configured to perform a subsequent operation of the frequency switching operation based on the frequency information FI stored in the memory 113. The subsequent operation in the control circuit 111 may be the same as those described in FIG. 2.

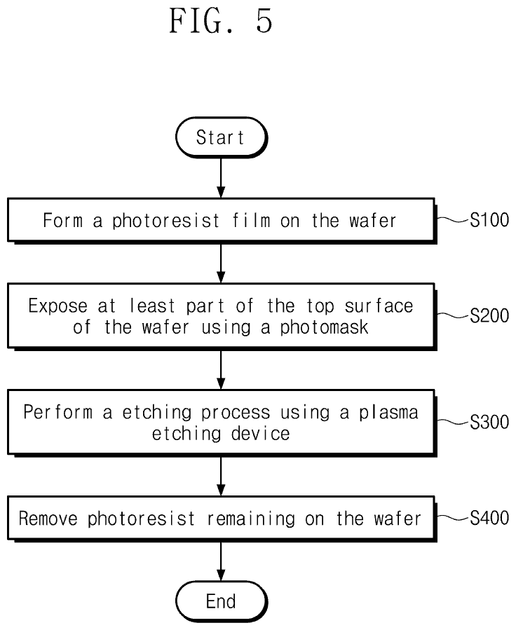

FIG. 5 is a flowchart showing an example of a method for manufacturing a semiconductor device, according to an embodiment of the present disclosure. An example of a semiconductor device manufacturing method may refer to a photolithography process.

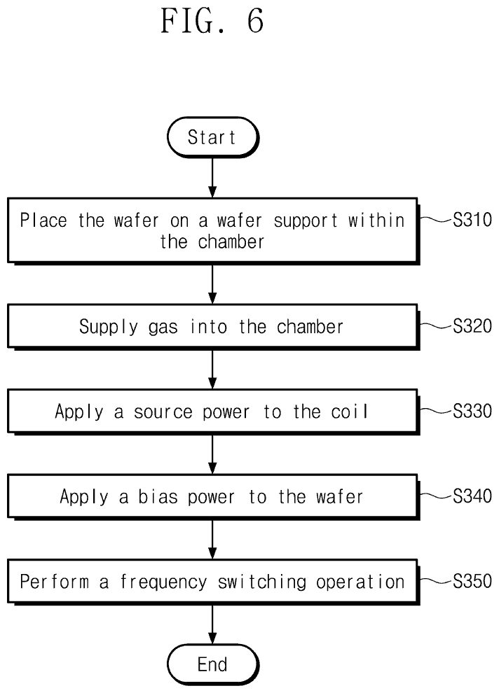

Referring to FIG. 5, in operation S100, a photoresist film may be formed on a wafer. In operation S200, a part of a top surface of the wafer may be exposed by removing a part of the photoresist film by using a photo mask. The photo mask may include a pattern corresponding to a circuit pattern to be formed on the wafer. In operation S300, an etching process may be performed by using the plasma etching device 100 according to an embodiment of the present disclosure. A specific example of a plasma etching process will be described later with reference to FIG. 6. After the etching process is completed, In operation S400, the photoresist film remaining on the wafer may be removed.

In a manufacturing process of a semiconductor device, operations S100 to S400 may be performed repeatedly. For example, to hierarchically form a plurality of circuit patterns on a wafer, a method of manufacturing a semiconductor device may include a plurality of cycles. Operations S100 to S400 may be performed in each cycle, and shapes of patterns formed on the photo mask in operation S200 in each cycle may be different from each other.

FIG. 6 is a flowchart showing an example of an etching process method, according to an embodiment of the present disclosure. FIG. 6 may show a specific method of performing the etching process in operation S300 of FIG. 5. Hereinafter, a method of performing an etching process by using the plasma etching device 100 of FIG. 1 will be described in detail.

Referring to FIGS. 1 and 6, in operation S310, the wafer WF is placed on the wafer support member 143 in the chamber 141. The photoresist film patterned through operations S100 and S200 may be formed on the top surface of the wafer WF. At the beginning of the etching process, the inside of the chamber 141 may be maintained in a vacuum state and may be referred to as the “vacuum chamber 141”.

In operation S320, the gas supply 142 may supply gas into the chamber 141.

In operation S330, the source power generator 110 may apply the source power signal SPS to the inductively-coupled antenna through the first match circuit 115. The controller 150 may generate the source control signal SCS, which includes an operating signal for allowing the source power generator 110 to operate.

The source power signal SPS may be applied to the coil to supply induced electromotive force to the plasma generating device 140. As the induced electromotive force is supplied to gas molecules inside the chamber 141 of the plasma generating device 140, plasma may be generated inside the chamber 141.

In operation S340, the bias power generator 120 may apply the source power signal SPS to the wafer support member 143 inside the chamber 141 through the second match circuit 125. The controller 150 may generate the bias control signal BCS, which includes an operating signal for allowing the bias power generator 120 to operate. The bias power signal BPS may be applied to the wafer through the wafer support member 143, and the wafer WF or the wafer support member 143 may also be referred to as a “cathode electrode”. In an embodiment, the operation S340 is performed after the plasma is generated in the operation S330. The present disclosure is not limited thereto. In an embodiment, the operation S340 and the operation S330 may be performed at the same time.

As the bias power signal BPS is applied to the wafer WF, radicals of plasma generated inside the chamber 141 may be accelerated toward the top surface of the wafer WF. As the radicals or ions collide with a part (i.e., an area exposed on the wafer WF) where the photoresist film is not formed on the top surface of the wafer WF, an etching process may be performed on a target layer disposed on the wafer.

As the bias power generator 120 operates in operation S340, in operation S350, the source power generator 110 may perform a frequency switching operation according to an embodiment of the present disclosure. Hereinafter, the frequency switching operation according to an embodiment of the present disclosure will be described in detail.

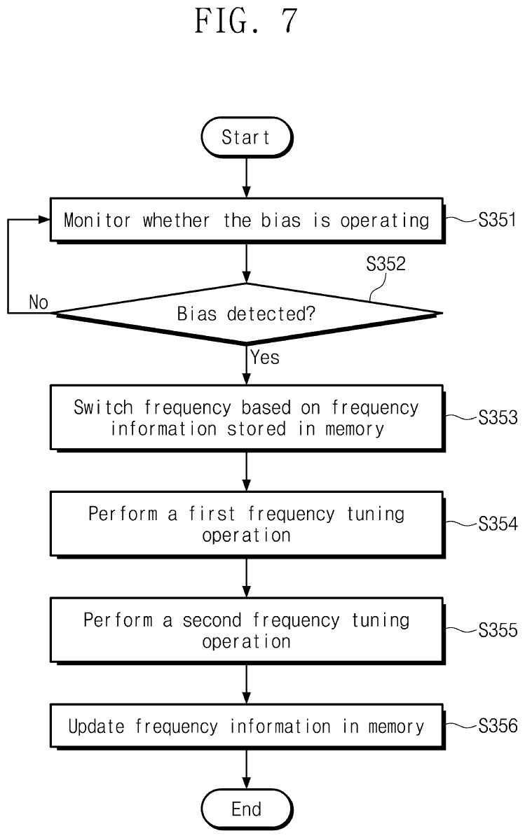

FIG. 7 is a flowchart showing an example of a frequency switching operation, according to an embodiment of the present disclosure. Hereinafter, a method of performing a frequency switching operation in the source power generator 110 of the plasma etching device 100 will be described with reference to FIGS. 1 to 4.

Referring to FIG. 7, in operation S351, the source power generator 110 may monitor whether the bias power generator 120 is operating. For example, the source power generator 110 may detect whether the bias power generator 120 is operating, by using at least one of the first to third monitoring circuits (hereinafter referred to as a “monitoring circuit”) described in FIGS. 2 to 4.

The source power generator 110 may perform automatic frequency tuning while monitoring the operation of the bias power generator 120. For example, the source power generator 110 may increase or decrease the frequency of the source power signal SPS such that the output current is maximized. The frequency tuning may be automatically performed by a frequency tuning algorithm inside the source power generator 110.

In operation S352, when the monitoring circuit determines that the bias power generator 120 is operating, the source power generator 110 may perform operation S353. When the monitoring circuit determines that the bias power generator 120 is not operating, the source power generator 110 may perform operation S351.

In operation S353, the control circuit 111 may be configured to perform the frequency switching operation based on the frequency information FI stored in the memory 113 in response to the result obtained as the monitoring circuit determines that the bias power generator 120 is operating. When performing the frequency switching operation, the control circuit 111 may switch the frequency of the source power signal based on the frequency value included in the frequency information. The control circuit 111 may control the RF generator 112 such that the frequency of the source power signal SPS is maintained at the switched frequency value during a first time interval P1.

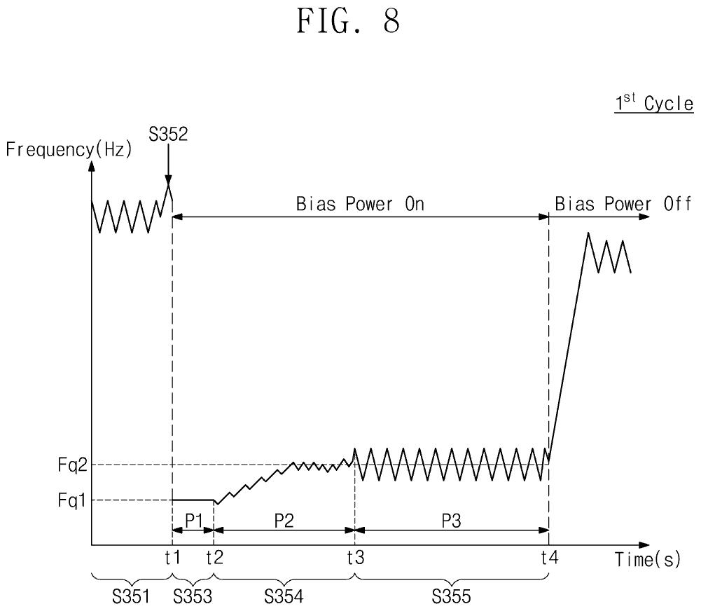

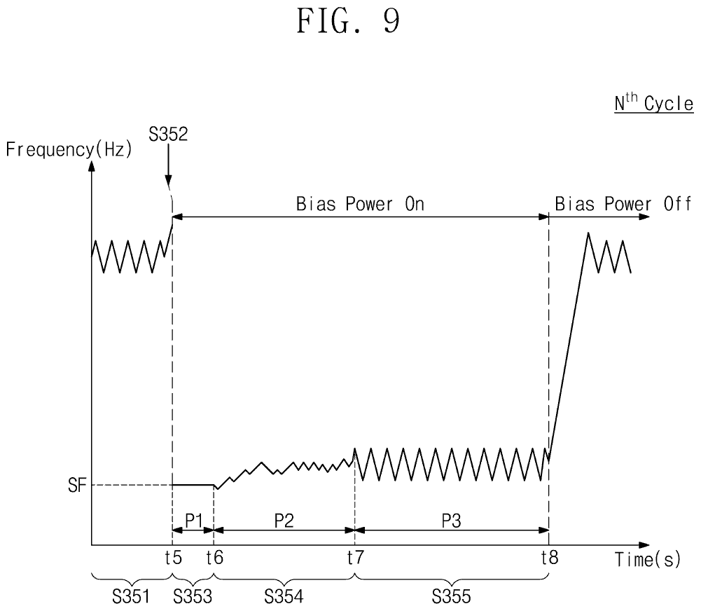

A specific method of performing a frequency switching operation in the control circuit 111 will be described later with reference to FIGS. 8 and 9.

In operation S354, after the frequency switching operation, the control circuit 111 may perform a first frequency tuning operation. When the first frequency tuning operation is performed, the frequency tuning operation may be performed by increasing or decreasing a frequency at a first unit interval such that the magnitude of the reflect wave measured inside the source power generator 110 is reduced. For example, the magnitude of the first unit interval may be equal to the minimum value of a unit at which the frequency is increased or decreased in an automatic frequency tuning operation.

The control circuit 111 may perform the first frequency tuning operation during a second time interval P2. In an embodiment, the second time interval P2, during which the first frequency tuning operation is performed, may be greater than the first time interval P1, during which the frequency switching operation is performed.

In operation S355, after performing the first frequency tuning operation, the control circuit 111 may perform a second frequency tuning operation. When performing the second frequency tuning operation, the source power generator 110 may perform a frequency tuning operation by increasing or decreasing the frequency at a second unit interval such that the magnitude of the output current increases. For example, the magnitude of the second unit interval may be equal to a unit at which the frequency is increased or decreased in an automatic frequency tuning operation. For example, while the second frequency tuning operation is performed, the magnitude of the second unit interval may vary. In other words, the second frequency tuning operation may be the automatic frequency tuning operation automatically performed by a frequency tuning algorithm.

The control circuit 111 may perform the second frequency tuning operation during a third time interval P3. In an embodiment, the third time interval P3, during which the second frequency tuning operation is performed, may be greater than the second time interval P2, during which the frequency switching operation is performed.

In an embodiment of the present disclosure, the control circuit 111 may gradually increase the amount of change in a frequency after performing a frequency switching operation through operations S353 to S355. Accordingly, in the case of the present disclosure, reflection loss may be further reduced by preventing a sudden change in the frequency of the source power signal SPS in the source power generator 110.

In operation S356, the monitoring circuit may detect that an operation of the bias power generator 120 ends. In response to the result obtained as the monitoring circuit determines that the operation of the bias power generator 120 has ended, the control circuit 111 may update the frequency information FI stored in the memory 113 based on a value of the optimized frequency of the source power signal SPS immediately before the end. The updated frequency information FI may further include a value of the optimized frequency in addition to an initial frequency value.

A method of manufacturing a semiconductor device may include a plurality of cycles, and operations S310 to S350 may be performed at each cycle. Hereinafter, a method of performing operation S350 in an initial cycle and the N-th cycle (‘N’ is a natural number of 2 or more) will be described in detail with reference to FIGS. 8 and 9.

FIG. 8 is a graph showing a frequency switching operation performed in an initial cycle of a semiconductor manufacturing process. Hereinafter, a method of performing a frequency switching operation in an initial cycle will be described with reference to FIG. 7. In an embodiment, the initial cycle may refer to a process performed for the first time by the plasma etching device 100 of FIG. 1, either after installation or following maintenance. The cycle may indicate how many times the plasma etching device 100 repeats performing a process. Before or during the initial cycle, an initial frequency of the source power signal SPS may be stored in the memory 113 of FIG. 2 as the frequency information FI. The initial frequency value (i.e., the first frequency value) may be input by an operator or may correspond to a frequency of the source power signal SPS applied prior to the maintenance. The present disclosure is not limited thereto. In an embodiment, the initial cycle may be set to one of repeated processes performed by the plasma etching device 100. The memory 113 may store a frequency value of the source power signal SPS applied when the previous process was completed as a second frequency value. The frequency information stored in the memory 113 may be updated using the second frequency value.

Referring to FIG. 8, at a first time point t1, the monitoring circuit may determine that the bias power generator 120 is operating (S352).

The control circuit 111 may perform a frequency switching operation based on the determination result of the monitoring circuit (S353) in a first time interval P1 of the semiconductor manufacturing process. The control circuit 111 may set the frequency of the source power signal SPS based on the frequency information FI stored in the memory 113. In the first time interval P1 of the initial cycle, a first frequency value Fq1 (i.e., an initial frequency value) may be initially stored in the memory 113 as the frequency information FI, and the control circuit 111 may set the first frequency value Fq1 as the frequency of the source power signal SPS. For example, the first frequency value Fq1 may be an initial value set by a user input from the controller 150. The control circuit 111 may keep the first frequency value Fq1 of the source power signal SPS during the first time interval P1 (between the first time point t1 and a second time point t2).

At the second time point t2, the control circuit 111 may perform a first frequency tuning operation (S354). In the first frequency tuning operation (S354), the first frequency value Fq1 of the source power signal SPS may be adjusted. The control circuit 111 may perform a frequency tuning operation by increasing or decreasing the frequency of the source power signal SPS at a first unit interval during a second time interval P2 (between the second time point t2 and a third time point t3).

At the third time point t3, the control circuit 111 may perform a second frequency tuning operation (S355). The control circuit 111 may perform a frequency tuning operation by increasing or decreasing the frequency of the source power signal SPS at a second unit interval during the third time interval P3 (between the third time point t3 and a fourth time point t4).

In the fourth time point t4, the monitoring circuit may detect that an operation of the bias power generator 120 ends. In response to the result obtained as the monitoring circuit determines that the operation of the bias power generator 120 has ended, the control circuit 111 may update the frequency information FI stored in the memory 113 based on a value of the optimized frequency of the source power signal SPS immediately before the end or based on a frequency value of the source power signal SPS at the time when the operation of the bias power generator 120 ended. For example, the memory may store the frequency value (i.e., a second frequency value) of the source power signal at the time when the operation of the bias power generator 120 ended. For example, the updated frequency information FI may include a second frequency value, which is the value of the optimized frequency or the frequency of the source power signal SPS at the time when the operation of the bias power generator 120 ended, in addition to the first frequency value (i.e., the initial frequency value). In an embodiment, the frequency information FI may be updated based on the first frequency value Fq1 and the second frequency value Fq2 using the following equation: SF=α*Fq1+(1−α)*Fq2, where SF represent a frequency value of the updated frequency information, and α may be a weight value in a range [0, 1]. After completing the first cycle, the frequency information FI updated using the first frequency value Fq1 and the second frequency value Fq2 may be an initial frequency for the frequency switching operation in the second cycle immediately after the first cycle.

FIG. 9 is a graph showing a frequency switching operation performed in an N-th cycle of the semiconductor manufacturing process. Hereinafter, a method of performing a frequency switching operation in the N-th cycle (‘N’ is 2 or more) will be described with reference to FIG. 7.

Referring to FIG. 9, at a fifth time point t5, a monitoring circuit may determine that the bias power generator 120 is operating (S352).

The control circuit 111 may perform a frequency switching operation based on the determination result of the monitoring circuit (S353). The control circuit 111 may set the frequency of the source power signal SPS based on the frequency information FI stored in the memory 113.

The control circuit 111 may set the frequency of the source power signal SPS based on the frequency information FI, which includes a value of the optimized frequency stored in the previous cycle or the frequency value of the source power signal SPS at the time the previous (N−1)th cycle of the semiconductor manufacturing process was completed. The frequency information FI stored in the memory 113 may include a plurality of frequency values. The control circuit 111 may set the frequency of the source power signal SPS based on at least one or more frequency values among the plurality of frequency values of the frequency information FI.

For example, in the N-th cycle, the frequency information FI stored in the memory 113 may further include second to N-th frequency values, which are frequency values optimized in second to (N−1)-th cycles, in addition to the first frequency value being the initial frequency. For example, after completing the first cycle, the memory may store the second frequency value in addition to the first frequency value, and after completing the (N−1)th cycle, the memory may store the Nth frequency value in addition to the first to (N−1)th frequency values.

In an embodiment, as in Equation 1 below, the control circuit 111 may set a frequency SF of the source power signal SPS based on the (N−1)-th frequency value Fq(N−1) and the N-th frequency value FqN.

$$SF = α * Fq ( N - 1 ) + ( 1 - α ) * FqN \qquad [ Equation 1 ]$$

In Equation 1, α may be a value in a range [0, 1] and may mean a weight assigned to the frequency value. The controller 150 may control the frequency switching operation performed in the control circuit 111 by controlling a value of α.

From a sixth time point t6 to a seventh time point t7, the control circuit 111 may perform a first frequency tuning operation during the second time interval P2 (S354). From the seventh time point t7 to an eighth time point t8, the control circuit 111 may perform a second frequency tuning operation during the third time interval P3 (S355).

In an embodiment of the present disclosure, the frequency switching operation of the next cycle may be performed based on the stored frequency by storing the optimized frequency in each of a plurality of cycles of a semiconductor manufacturing method in the source power generator 110. Accordingly, in the case of the present disclosure, reflection loss may be reduced by minimizing the time required to optimize a frequency in cycles at which the frequency switching operation is performed repeatedly.

The above-mentioned description refers to detailed embodiments for implementing the present disclosure. The present disclosure may include embodiments in which a design is changed simply or which are easily changed, as well as an embodiment described above. In addition, technologies that are easily changed and implemented by using the above embodiments may be included in the present disclosure. While the present disclosure has been described with reference to embodiments described above, it will be apparent to those of ordinary skill in the art that various changes and modifications may be made thereto without departing from the spirit and scope of the present disclosure as set forth in the following claims.

According to an embodiment of the present disclosure, it is possible to provide a plasma etching device for reducing reflection loss due to frequency changes.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A plasma etching device comprising:
a source power generator configured to generate a source power signal based on a source control signal;
a bias power generator configured to generate a bias power signal based on a bias control signal;
an inductively-coupled antenna provided with the source power signal; and
a plasma generating device provided with the bias power signal,
wherein the source power generator is configured to:
detect whether the bias power generator is operating; and
perform, in response to detecting of the bias power generator being operating, a frequency switching operation by switching a frequency of the source power signal.

2. The plasma etching device of claim 1,
wherein the source power generator further includes:
a control circuit configured to generate a frequency control signal to control the frequency of the source power signal; and
an RF generator configured to generate the source power signal based on the frequency control signal; and
a memory configured to store frequency information,
wherein the control circuit is configured to perform the frequency switching operation based on the frequency information.

3. The plasma etching device of claim 2,
wherein the source power generator further includes:
a voltage sensor configured to measure a voltage of an output terminal of the RF generator;
a current sensor configured to measure a current output from the RF generator; and
a first monitoring circuit configured to determine whether the bias power generator is operating, based on at least one of voltage information measured by the voltage sensor and current information measured by the current sensor, and
wherein the control circuit is configured to perform the frequency switching operation in response to the first monitoring circuit determining that the bias power generator is operating.

4. The plasma etching device of claim 3,
wherein when an effective value of the voltage information is greater than or equal to a first threshold value, the first monitoring circuit is configured to determine that the bias power generator is operating, and
wherein the voltage information represents an AC voltage of the source power signal generated by the RF generator.

5. The plasma etching device of claim 3,
wherein when an effective value of the current information is greater than or equal to a second threshold value, the first monitoring circuit determines that the bias power generator is operating, and
wherein the current information represents an AC current of the source power signal generated by the RF generator.

6. The plasma etching device of claim 2,
wherein the source power generator further includes:
a reflect wave sensor configured to detect a reflect wave of the source power signal generated from the RF generator; and
a second monitoring circuit configured to determine the bias power generator is operating, based on the reflect wave detected by the reflect wave sensor, and wherein the control circuit is configured to perform the frequency switching operation in response to the second monitoring circuit determining that the bias power generator is operating.

7. The plasma etching device of claim 6,
wherein when a magnitude of a reflectance coefficient of the reflect wave is greater than or equal to a third threshold value, the second monitoring circuit is configured to determine that the bias power generator is operating.

8. The plasma etching device of claim 2,
wherein the source power generator further includes:
a third monitoring circuit configured to determine whether the bias power generator is operating, based on detection of whether the bias control signal is generated, and
wherein the control circuit is configured to perform the frequency switching operation in response to the third monitoring circuit determining that the bias power generator is operating.

9. The plasma etching device of claim 2,
wherein the control circuit is configured to update the frequency information stored in the memory based on a value of a frequency of the source power signal identified in response to a result of determining that an operation of the bias power generator ends.

10. The plasma etching device of claim 1,
wherein the inductively-coupled antenna includes a coil to which the source power signal is applied, and
wherein the plasma generating device includes:
a wafer support member to which the bias power signal is applied; and
a chamber including the wafer support member.

11. A device comprising:
a control circuit configured to generate a frequency control signal to control a frequency of a source power signal;
an RF generator configured to generate the source power signal based on the frequency control signal;
a monitoring circuit configured to determine whether a bias power generator is operating; and
a memory configured to store frequency information,
wherein the control circuit is configured to perform a frequency switching operation based on the frequency information in response to the monitoring circuit determining that the bias power generator is operating.

12. The device of claim 11, further comprising:
a voltage sensor configured to measure a voltage of an output terminal of the RF generator; and
a current sensor configured to measure a current output from the RF generator,
wherein the monitoring circuit is configured to determine whether the bias power generator is operating, based on at least one of voltage information measured by the voltage sensor and current information measured by the current sensor.

13. The device of claim 11, further comprising:
a reflect wave sensor configured to detect a reflect wave of the source power signal generated from the RF generator,
wherein the monitoring circuit is configured to determine the bias power generator is operating, based on the reflect wave detected by the reflect wave sensor.

14. The device of claim 11,
wherein the monitoring circuit is configured to determine whether the bias power generator is operating, based on a bias control signal for controlling the bias power generator.

15. The device of claim 11,
wherein the control circuit is configured to:
after performing the frequency switching operation, perform a first frequency tuning operation by increasing and decreasing a value of the frequency of the source power signal at a first unit interval during a first time; and
perform, after the performing of the first frequency tuning operation, a second frequency tuning operation by increasing and decreasing a value of the frequency of the source power signal at a second unit interval during a second time,
wherein the second unit interval is greater than or equal to the first unit interval, and
wherein the second time is longer than the first time.

16. A method of operating a device including a source power generator and a bias power generator, wherein the source power generator includes:
a control circuit configured to generate a frequency control signal including information for controlling a frequency of a source power signal;
an RF generator configured to generate the source power signal based on the frequency control signal; and
a monitoring circuit configured to detect whether a bias power generator is operating; and
a memory configured to store frequency information,
the method comprising:
determining, by the monitoring circuit, whether the bias power generator is operating; and
performing, by the control circuit, a frequency switching operation based on the frequency information in response to a result of determining that the bias power generator is operating.

17. The method of claim 16, further comprises:
after performing the frequency switching operation, performing, by the control circuit, a first frequency tuning operation by increasing and decreasing the frequency value of the source power signal at a first unit interval during a first time; and
after performing the first frequency tuning operation, performing, by the control circuit, a second frequency tuning operation by increasing and decreasing the frequency value of the source power signal at a second unit interval during a second time,
wherein the second unit interval is greater than or equal to the first unit interval, and
wherein the second time is longer than the first time.

18. The method of claim 16, further comprising:
detecting, by the monitoring circuit, an operation of the bias power generator ends; and updating, by the control circuit, the frequency information stored in the memory based on a value of an optimized frequency of the source power signal immediately before the end in response to a result of determining that the operation of the bias power generator ends.

19. The method of claim 18, wherein the updated frequency information includes a first frequency value and a second frequency value, and
further comprising:
performing, by the control circuit, frequency switching based on the updated frequency information.

20. The method of claim 19, wherein the performing of the frequency switching is by using Equation 1:
$$SF = α * Fq 1 + ( 1 - α ) * Fq 2 ,$$
wherein in Equation 1, the SF denotes a switched frequency value, the Fq1 denotes the first frequency value, the Fq2 denotes the second frequency value, and the α denotes a value in a range [0, 1].
